(19) United States
(12) Patent Application Publication
(10) Pub. No.: US 2014/0231786 A1
(43) Pub. Date: Aug. 21, 2014

(54) Blue Phosphorescent Organic Light Emitting Device Having a Minimal Lamination Structure

(71) Applicant: Dong Yoon Shin, Seoul (KR)

(72) Inventor: Dong Yoon Shin, Seoul (KR)

(73) Assignee: YOUL CHON CHEMICAL CO., LTD., Seoul (KR)

(21) Appl. No.: 14/346,073

(22) PCT Filed: Jun. 29, 2012
(86) PCT No.: PCT/KR2012/005210

§ 371 Date: Mar. 20, 2014

(30) Foreign Application Priority Data
Sep. 28, 2011 (KR) 10-2011-0098213

(51) Int. Cl. H01L 51/50; H01L 51/52

(52) U.S. Cl. CPC H01L 51/5012; H01L 51/5206; H01L 51/5072
USPC 257/40

(57) ABSTRACT

Disclosed is a blue phosphorescent organic light emitting device having a minimal lamination structure. The device includes an anode; an emitting layer formed on the anode and including a host and a dopant; an electron transport layer formed on the emitting layer; and a cathode formed on the electron transport layer. A difference between a work function of the anode and a high occupied molecular orbital (HOMO) energy level of the emitting layer is less than 1.0 eV, and a difference between a low occupied molecular orbital (LUMO) energy level of the emitting layer and an LUMO energy level of the electron transport layer is less than 1.0 eV.

### TECHNICAL FIELD

The present invention relates to a blue phosphorescent organic light emitting device having a minimal lamination structure. More specifically, the present invention relates to a blue phosphorescent organic light emitting device having a minimal lamination structure capable of not only showing excellent properties as a blue phosphorescent device, but also being simply manufactured and having a thin thickness due to the minimal lamination structure, to thereby be practically useful in a flexible display, and the like.

### BACKGROUND ART

Speed as well as precision of information occupies an important part in the early 21st century, and thus an information display field occupies a very important part among various industrial fields. A display has moved from a known CRT display to a LCD that is a flat panel display capable of being carried, and, currently, the LCD is most frequently used. However, since the LCD is a photodetector, there is a technical limit in terms of brightness, light and darkness, viewing angle, and enlargement, and thus novel devices overcoming the disadvantages need to be developed, and one of the devices is an organic light-emitting device (hereinafter, referred to as ‘OLED’).

Academic and industrial researches of the OLED in the limelight as a next-generation display have been actively performed in various fields such as electric, electronics, materials, chemistry, physics, and optics. As a research result, a PM-mode OLED is introduced into some electronic apparatuses, for example, the PM-mode OLED is used in an external window of a cellular phone, and currently, researches and industrialization for applying an AM-mode OLED to mobile displays such as PDAs, cellular phones, and game machines are performed.

In addition, it is known that phosphorescent light-emitting materials as well as fluorescent light-emitting materials are capable of being used as the OLED, and recently a research thereof has been continuously conducted. The phosphorescent light emission is performed based on a mechanism that after electrons are transferred from the ground state to an excited state, singlet excitons are transferred to triplet excitons without luminescence through intersystem crossing, and the triplet excitons are then transferred to the ground state with luminescence. When the triplet excitons are transferred, since the triplet excitons is not capable of being directly transferred to the ground state but is transferred to the ground state after flipping of electron spins is performed, the phosphorescent light emission has a longer life-span (emission time) as compared to the fluorescent light emission. That is, an emission duration of the fluorescent light emission is just several nano seconds, but that of the phosphorescent light emission corresponds to several micro seconds, which are a relatively long time.

In general, a phosphorescent organic light emitting device (PhOLED) has a multilayer structure. FIG. 1 shows a lamination structure of a general phosphorescent organic light emitting device (PhOLED) according to the related art. Referring to FIG. 1, the PhOLED has a lamination structure including an anode consisting of ITO transparent electrode; a hole injection layer (HIL) formed on the anode; a hole transport layer (HTL) formed on the HIL; an emitting layer (EML) formed on the HTL; a hole blocking layer (HBL) formed on the EML; an electron transport layer (ETL) formed on the HBL; an electron injection layer (EIL) formed on the ETL; and a cathode formed on the EIL, wherein they are sequentially laminated on a substrate by methods such as deposition, and the like. In addition, the EML includes a host as an electric charge transport material and a dopant as a phosphorescent material.

If an electric field is applied to the PhOLED having the aforementioned structure, a hole is injected from the anode, an electron is injected from the cathode, and the injected holes and electrons pass through the hole transport layer (HTL) and the electron transport layer (ETL), respectively, and recombined in the emitting layer (EML) to form light-emitting excitons. In addition, the formed light-emitting excitons emit light while being transferred to a ground state.

In the case of a PhOLED, selection of the host directly affects luminous efficiency. Since light emission of a phosphorescent material occurs from a triplet, as triplet energy (ET) of a host is higher than triplet energy (ET) of a dopant, transferring of triplet energy (ET) from the host to the dopant may be effectively performed. Further, generally, since triplet energy (ET) is lower than singlet energy by about 1 eV, as compared to a fluorescent material, it is preferable to use a material having a large interval between a highest occupied molecular orbital (HOMO) and a lowest unoccupied molecular orbital (LUMO) as the host material. That is, if triplet energy of the host is lower than triplet energy of the dopant, since endothermic energy transferring is used, external luminous efficiency is reduced, but if triplet energy of the host is higher than triplet energy (ET) of the dopant, since exothermic energy transferring is used, high luminous efficiency is exhibited. Accordingly, triplet energy (ET) of the host should be high in order to increase luminous efficiency. In addition, the host should have excellent electrical properties such as charge mobility, and the like, and excellent thermal stability.

Further, in the case in which energy level of the host is extremely high, high energy barrier between the EML and the HTL is generated to increase a driving voltage and has difficulty in increasing luminous efficiency. The HOMO energy level of NPB mainly used as the existing HTL is 5.4 eV and the HOMO energy level of CBP, BAlq, TAZ, and the like, mainly used as the host of the existing EML is about 6.0 to 6.8 eV, and thus, a difference in HOMO energy level is about 0.6 eV or more to 1.4 eV, to show high energy barrier, such that a driving voltage may be increased and there is difficulty in increasing luminous efficiency. Therefore, in order to maximize injection of electric charge (hole and electron) into the EML to have high efficiency, the difference in HOMO energy level needs to be decreased. The above-described problem is remarkably shown in blue PhOLED having a wide band gap, and in order to solve the problem, many researches are still working on it.

For example, Korean Patent Registration No. 10-0454500 [Patent Document 1] discloses an organic light emitting device having a buffer layer formed between HTL and EML, and Korean Patent Registration No. 10-0777099 [Patent Document 2] discloses an organic light emitting device having a barrier relax layer formed between HTL and EML.

As described above, the existing PhOLED having high efficiency has a multilayer structure necessarily including HIL, HTL, and HBL and additionally including a buffer layer and a barrier relax layer in order to maximize injection of the hole into the EML.

However, since the PhOLED according to the related art including the above-mentioned Patent Documents has a multilayer structure having excessively stacked layers, a lot of processes for forming each layer should be performed to complicate a manufacturing process and to thicken a thickness of the device, such that there is difficulty in being used in a flexible display, and the like. In addition, in the case in which the existing multilayer structure is applied to a blue PhOLED, since the multilayer structure is not appropriate for blue property, it is difficult to show excellent properties as a device and a long life-span property. In particular, excellent properties as a device may not be obtained at a low voltage.

### Technical Problem

An object of the present invention is to provide a blue phosphorescent organic light emitting device having a minimal lamination structure capable of not only showing excellent properties as a blue phosphorescent device, but also being simply manufactured and having a thin thickness due to the minimal lamination structure, to thereby be practically useful in a flexible display, and the like.

### Technical Solution

In one general aspect, the present invention provides a blue phosphorescent organic light emitting device including:

an anode;

an emitting layer formed on the anode and including a host and a dopant;

an electron transport layer formed on the emitting layer; and

a cathode formed on the electron transport layer,

wherein a difference between a work function of the anode and a high occupied molecular orbital (HOMO) energy level of the emitting layer is less than 1.0 eV, and

a difference between a low occupied molecular orbital (LUMO) energy level of the emitting layer and an LUMO energy level of the electron transport layer is less than 1.0 eV.

The difference between the work function of the anode and the high occupied molecular orbital (HOMO) energy level of the emitting layer may be 0.1 to 0.9 eV, and the difference between the low occupied molecular orbital (LUMO) energy level of the emitting layer and the LUMO energy level of the electron transport layer may be 0.1 to 0.9 eV. The anode may contain tungsten oxide (WO₃).

### Advantageous Effects

According to the present invention, there is provided a blue phosphorescent organic light emitting device having a minimal lamination structure capable of not only showing excellent properties as a blue phosphorescent device, but also being simply manufactured and having a thin thickness due to the minimal lamination structure. In addition, due to the thin thickness, flexible property may be improved, such that the blue phosphorescent organic light emitting device having a minimal lamination structure may be practically useful in a flexible display, and the like.

### DESCRIPTION OF DRAWINGS

FIG. 1 is a schematic diagram showing a lamination structure of a blue phosphorescent organic light emitting device (PhOLED) according to the related art;

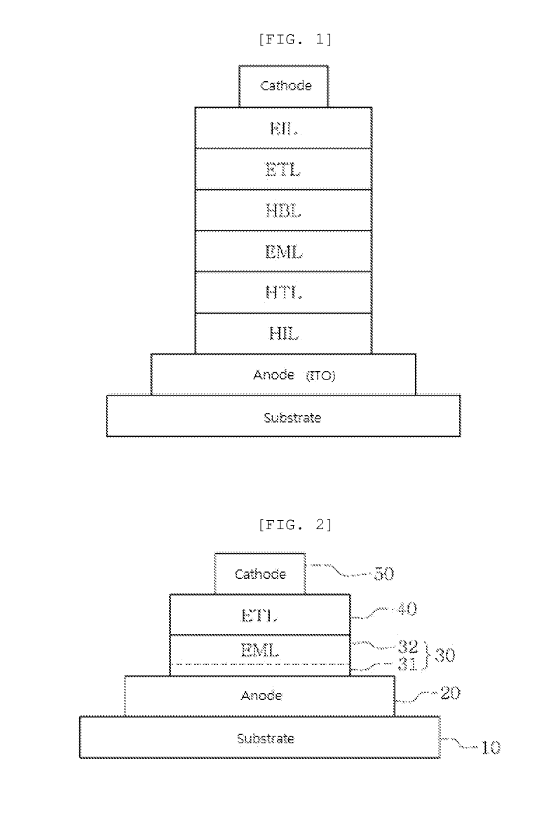

FIG. 2 is a schematic diagram showing a lamination structure of a blue phosphorescent organic light emitting device (PhOLED) according to the present invention;

FIGS. 3 to 6 are energy band diagrams of the PhOLEDs manufactured by Examples and Comparative Examples of the present invention, respectively; and

FIGS. 7 and 8 are graphs showing device property evaluation result of the PhOLEDs manufactured by Examples and Comparative Examples of the present invention.

### DETAILED DESCRIPTION OF MAIN ELEMENTS

10: Substrate 20: Anode
30: Emitting Layer 40: Electron Transport Layer
50: Cathode

### BEST MODE

Hereinafter, embodiments of the present invention will be described in detail with reference to the accompanying drawings.

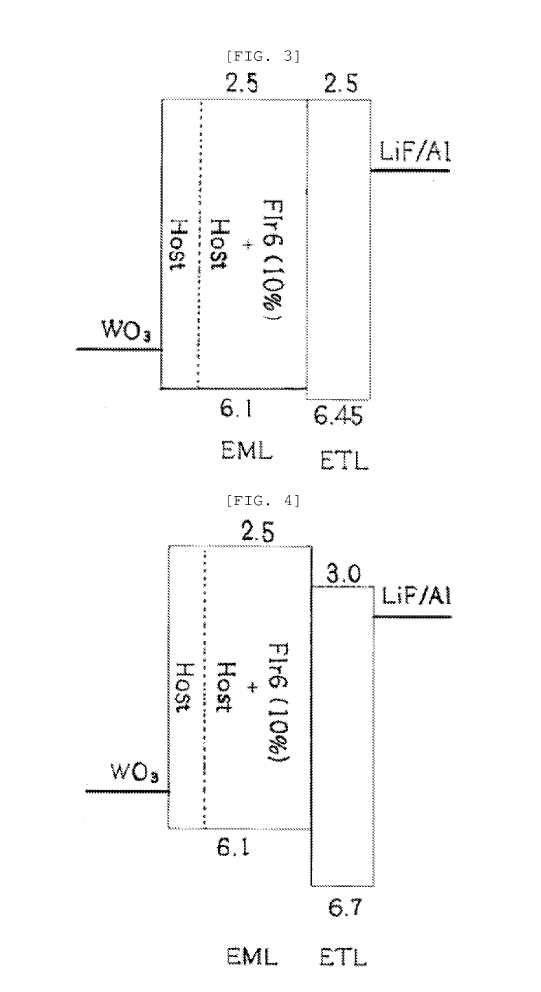

FIG. 2 shows a lamination structure of a blue phosphorescent organic light emitting device (PhOLED) according to a desirable embodiment of the present invention.

The blue PhOLED according to the embodiment of the present invention has a minimal lamination structure without a hole injection layer (HIL) and a hole transport layer (HTL) that are necessarily included in the PhOLED according to the related art. More specifically, referring to FIG. 2, the blue PhOLED according to the embodiment of the present invention has a lamination structure including an anode 20; an emitting layer (EML) 30 formed on the anode 20; an electron transport layer (ETL) formed on the EML 30; and a cathode 50 formed on the ETL 40. That is, the blue PhOLED according to the embodiment present invention has a minimal lamination structure in which the HIL and the HTL are not formed between the anode 20 and the EML 30. In addition, as shown in FIG. 2, a substrate 10 supporting the layers may be included therein.

Further, the blue PhOLED according to the embodiment of the present invention has a minimal lamination structure without the HIL and the HTL and satisfies the following two conditions.

difference between work function of the anode 20 and a high occupied molecular orbital (HOMO) energy level of the emitting layer 30: Less than 1.0 eV

difference between a low occupied molecular orbital (LUMO) energy level of the emitting layer 30 and an LUMO energy level of the electron transport layer 40: Less than 1.0 eV

According to the embodiment of the present invention, the above-described two conditions are satisfied, and thus, even though the HIL and the HTL that are necessarily formed in the related art are excluded, excellent device properties may be provided. In particular, the device shows excellent properties such as high brightness (cd/A), superior luminous efficiency (lm/W), and the like.

The substrate 10 is not limited. It is preferred that the substrate 10 has supporting force, and for example, may be selected from a glass substrate, a polymer substrate, and the like. The substrate 10 may be selected from the polymer substrate when considering flexibility, and as a specific example thereof, a film containing at least one resin selected from polyethylene terephthalate (PET), polyethylene naphthalate (PEN), polycarbonate (PC), and the may be used.

The anode 20 is used in consideration of the HOMO energy level with the emitting layer 30. Specifically, the anode 20 in which a difference between a work function thereof and the HOMO energy level of the emitting layer 30 is less than 1.0 eV is used. Here, in the case in which the difference between the work function of the anode 20 and the HOMO energy level of the emitting layer 30 is 0.1 eV or more, excellent device properties as the desired minimal lamination structure in the embodiment of the present invention may not be obtained. That is, according to the embodiment of the present invention, in the case in which the difference between the work function of the anode 20 and the HOMO energy level of the emitting layer 30 is less than 0.1 eV, even though the HIL and the HTL are excluded, an injection of holes may be maximized, such that excellent device properties may be obtained. Preferably, the difference between the work function of the anode 20 and the HOMO energy level of the emitting layer 30 is close to 0.1 ev, more preferably, 0.1 to 0.9 eV.

The anode 20 may be determined on kinds of materials configuring the emitting layer 30, in particular, a kind of a host, and it is preferred to have work function of 5.8 to 6.8 eV. In the case in which the anode 20 has the work function within the above-described range, an energy barrier with the emitting layer 30 is minimized, such that injection of holes into the emitting layer 30 is maximized.

The anode 20 is not limited as long as the difference between the work function of the anode 20 and the HOMO energy level of the emitting layer 30 is less than 1.0 eV, and preferably, the anode contains tungsten oxide (WO₃). More specifically, the anode 20 may be formed by depositing tungsten oxide (WO₃) formed on the substrate 10 or by depositing a mixture containing tungsten oxide (WO₃) and other conductive metal oxides. For example, the anode 20 may be formed of deposited material containing tungsten oxide (WO₃) at least and further containing at least one metal oxide selected from aluminum oxide (Al₂O₃), zinc oxide (ZnO), and the like. The tungsten oxide (WO₃) has a work function of about 5.9 eV, such that an energy barrier with the emitting layer 30 is minimized, which is preferred in the embodiment of the present invention.

The emitting layer 30 is not limited, but is preferred to implement a blue phosphorescent. Specifically, it is preferred that the emitting layer 30 includes a host and a dopant capable of implementing a blue phosphorescent. The host and the dopant are not particularly limited as long as they are generally used.

The host is not limited as long as a material enables transport of electric charges, and general examples thereof may include at least one selected from 4,4′-N,N-dicarbazolebiphenyl (CBP), bis(2-methyl-8-quinolinolato)(para-phenolato)aluminum(III) (BAlq), triazole (TAZ), 1,3-N,N-dicarbazolebenzene (mCP), bis(2-methyl-8-quinolinolato)(triphenylsiloxy)aluminum(III) (SAlq), 3-(biphenyl-4-yl)-5-(4-dimethylamino)4-(4-ethylphenyl)-1,2,4-triazole (p-EtTAZ), tris(para-ter-phenyl-4-yl)amine (p-TTA), 5,5-bis(dimesitylboryl)-2,2-bithiophene (BMB-2T), and the like. It is preferred that a compound having a specific bond structure so as to implement the blue phosphorescent is used as the host, which will be described later.

In addition, the dopant may be at least one selected from typically used FIr6, FIrpic, and the like, and additionally, the dopant may be selected from 4-dicyanomethylene-2-methyl-6-(para-dimethylaminostyryl)-4H-pyran), dicyanomethylene-2-methyl-6-(julolydine-4-yl-vinyl)-4H-pyran, dicyanomethylene-2-methyl-6-(1,1,7,7-tetramethyljulolydyl-9-enyl)-4H-pyran, dicyanomethylene-2-tertiarybutyl-6-(1,1,7,7-tetramethyljulolydyl-9-enyl)-4H-pyran, dicyanomethylene-2-isopropyl-6-(1,1,7,7-tetramethyljulolydyl-9-enyl)-4H-pyran, and the like.

The emitting layer 30 preferably includes a host thin film layer 31 formed on the anode 20 and a phosphorescent material layer 32 formed on the host thin film layer 31 as shown in FIG. 2. As described above, in the case in which the host thin film layer 31 is formed between the anode 20 and the phosphorescent material layer 32, the host thin film layer 31 allows holes induced from the anode 20 to be effectively transferred to the phosphorescent material layer 32, thereby improving device efficiency.

The host thin film layer 31 is formed by coating host on the anode 20. The host thin film layer 31 is not particularly limited, but may have a thickness of 20 to 100 nm.

In addition, the phosphorescent material layer 32 may be formed in a thickness of 150 to 500 nm on the host thin film layer 31. The phosphorescent material layer 32 consists of a mixture of a host and a dopant. The phosphorescent material layer 32 may be formed by mixing 5 to 25 mol % of dopant with the host. That is, the host and the dopant may have a molar ratio of 100:5 to 25. In addition, it is preferred that a host configuring the host thin film layer 31 and a host configuring the phosphorescent material layer 32 are the same material.

The electron transport layer 40 is used in consideration of an LUMO energy level. Specifically, the electron transport layer 40 in which a difference between the LUMO energy level thereof and the LUMO energy level of the emitting layer 30 is less than 1.0 eV is used. Accordingly, injection of electrons is effectively achieved, such that high efficiency due to the minimal lamination structure may be obtained. That is, even though additional electron injection layer (EIL) is not formed between the electron transport layer 40 and the cathode 50, electrons induced from the cathode 50 are effectively injected into the emitting layer 30, such that the minimal lamination structure may be obtained and the device having high efficiency property may be achieved. Here, in the case in which the difference between the LUMO energy level of the electron transport layer 40 and that of the emitting layer 30 is 1.0 eV or more, due to high energy barrier, it is difficult for electrons to be effectively injected into the emitting layer 30, such that formation of the electron injection layer (EIL) is inevitable, and high efficiency due to the minimal lamination structure which is desirable in the embodiment of the present invention may not be achieved.

According to the preferred embodiment of the present invention, the difference between the LUMO energy level of the emitting layer 30 and that of the electron transport layer 40 is preferably 0.1 to 0.9 eV. In the case of having the difference in the energy level as described above, effective injection of electrons and blocking of holes are simultaneously satisfied, such that highly efficient device property may be obtained. That is, the electrons may be effectively injected and even though additional hole blocking layer (HBL) is not formed between the emitting layer 30 and the cathode 50, transferring of the holes to the anode 50 are effectively blocked, such that the minimal lamination structure and high efficiency may be obtained.

More specifically, in the case in which the difference between the LUMO energy level of the emitting layer 30 and that of the electron transport layer 40 is less than 0.1 eV (for example, the difference in the LUMO energy level is 0.0 eV), the hole blocking may not be effectively achieved, such that formation of the HBL is inevitable. In addition, in the case in which the difference in the LUMO energy level is 0.9 eV or less, the injection of electrons into the emitting layer 30 may be easily achieved.

The electron transport layer 40 is not limited as long as the layer is made of a compound having the difference in the LUMO energy level between the electron transport layer 40 and the emitting layer 30 less than 1.0 eV, and for example, a compound in which the LUMO energy level (in general, a negative number) measured by the general measurement of the energy level is 2.4 to 3.2 eV may be used. Preferably, as the electron transport layer 40, a compound in which the LUMO energy level is 2.9 to 3.1 eV (3.0±0.1 eV) may be used. In particular, the above-described range of the LUMO energy level is preferred in the case in which FIr6 is used as the blue phosphorescent dopant of the emitting layer 30. As described above, in the case in which the LUMO energy level of the electron transport layer 40 is 2.9 to 3.1 eV, the electron injection and the hole blocking may be maximized, such that highly efficient and excellent device properties may be obtained.

According to more specific embodiment of the present invention, the electron transport layer 40 may include at least one selected from the following compounds represented by Chemical Formulas 1 and 2:

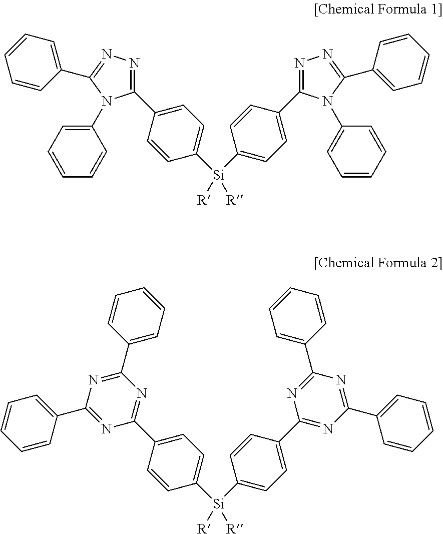

In Chemical Formulas 1 and 2, R′ and R″ are the same as each other or different from each other and each selected from hydrogen, an aliphatic compound, and an aromatic compound. In Chemical Formulas 1 and 2, R′ and R″ may be selected from hydrogen; C1 to C20 alkyl group; C6 to C20 aryl group; C3 to C20 heteroaryl group; alkyl group in which C3 to C20 heteroaryl is substituted; aryl group in which C1 to C20 alkyl or C3 to C20 heteroaryl is substituted, and the like. Preferably, R′ and R″ are each selected from alkyl group (methyl group, ethyl group, propyl group, butyl group, and the like) or phenyl group.

The compounds represented by Chemical Formulas 1 and 2 are materials having the LUMO energy level of 2.4 to 3.2 eV, and therefore, the difference in the HOMO energy level between the emitting layer 30 and the compounds as well as the difference in the LUMO energy level between the emitting layer 30 and the compounds are not large, such that the compounds are useful in the embodiment of the present invention.

The electron transport layer 40 preferably includes the compound represented by Chemical Formula 2 above at least. Specifically, the electron transport layer 40 may be configured of the compound represented by Chemical Formula above or may be configured by mixing the compound represented by Chemical Formula 2 with the compound represented by Chemical Formula 1.

The anode 50 is not limited as long as it is generally used. The cathode may be selected from metal. The cathode 50 may contain one or two or more alloys selected from Al, Ca, Mg, Ag, and the like, preferably, a material obtained by coating Al or an alloy containing Al with LiF.

In addition, in the embodiment of the present invention, a thickness of each layer is not limited. Further, each layer may be formed by general methods, for example, vacuum deposition methods such as a sputtering method, and the like, depending on each layer, or by performing liquid-coating and then drying processes or performing coating and then firing processes, and the like, but the method of forming each layer is not limited thereto.

The blue PhOLED according to the embodiment of the present invention as described above has excellent device properties. In addition, since the electron injection layer (EIL) and/or hole blocking layer (HBL) as well as the HIL and the HTL that are necessarily included in the PhOLED according to the related art are excluded in the blue PhOLED according to the embodiment of the present invention, the blue PhOLED has a minimal lamination structure. In addition, due to the minimal lamination structure, the blue PhOLED may be simply manufactured and have a thin thickness to thereby be practically useful in a flexible display, and the like.

Meanwhile, the host configuring the emitting layer 30 preferably includes a compound which will be described below. The host to be described below has high triplet energy of 3.0 eV or more and excellent charge mobility and thermal stability, thereby being preferably applied to the embodiment of the present invention.

Specifically, it is preferred that the host configuring the emitting layer 30 has a structure where a carbazole compound is bonded around a central atom. In this case, the central atom is selected from Group 14 elements, and two or three carbazole compounds are bonded around the central atom selected from the Group 14 element. In addition, the carbazole compound has a structure where at least one alkyl groups (CₙH₂ₙ₊₁—) are substituted in a molecule. The central atom is preferably selected from Si (silicon), Ge (germanium), or C (carbon), and more preferably selected from Si or Ge.

In the present specification, ‘carbazole’ is generally named, and means a matter where two 6-membered benzene rings are bonded to both sides of a 5-membered ring including nitrogen (N) (refer to the following Chemical Formula 4).

Further, in the present specification, ‘carbazole compound’ means a carbazole-based compound including at least one carbazole in the molecule. That is, in the present specification, the carbazole compound may include one or two or more carbazoles in the molecule, and optionally further include another compound in addition carbazole. Specifically, the carbazole compound may have one carbazole or two or more carbazoles in the molecule. In addition, the carbazole compound may include other compounds, for example, arylene (benzene cycle and the like), a heterocycle, and the like in addition to carbazole. In addition, the carbazole compound has a structure where at least one alkyl groups (CₙH₂ₙ₊₁—) are substituted in a molecule. In this case, the alkyl group is substituted in carbazole.

Accordingly, in the embodiments of the present invention, as defined above, the carbazole compound includes at least one carbazole in the molecule and at least one alkyl group is substituted in carbazole. In this case, the alkyl group is preferably substituted in a benzene cycle of carbazole. Carbazole has two benzene cycles, and in this case, the alkyl group may be substituted in at least one (any one or both two) of the two benzene cycles. In addition, one or two or more alkyl groups may be substituted in one benzene cycle.

Further, the alkyl group is not limited. That is, the number of carbon atoms of the alkyl group is not limited. The alkyl group may be selected from, for example, C1 to C20 alkyl group. Specific examples of the alkyl group may be selected from a methyl group, an ethyl group, a propyl group, a butyl group, and the like, but are not limited thereto. In addition, the propyl group includes n-propyl group and iso-propyl group, and the butyl group includes n-butyl group, iso-butyl group, and tertiary-butyl group. Moreover, two or three carbazole compounds are bonded around the central atom, and in this case, two or three carbazole compounds may be the same as or different from each other.

According to the embodiment of the present invention, a compound represented by the following Chemical Formula 3 may be used as the host.

(R1)ₙ-M-(R2)₄₋ₙ Chemical Formula 3

in Chemical Formula 3, M is a Group 14 element. M is preferably Si, Ge or C as described above. In addition, in Chemical Formula 3 above, n is 2 or 3 and R1 is a carbazole compound in which an alkyl group is substituted in carbazole.

In Chemical Formula 3 above, R2 not limited. R2 may be selected from hydrogen, an aliphatic compound, and an aromatic compound. In addition, R2 may be a heterocyclic compound as an aliphatic compound. Specific examples of R2 may be selected from hydrogen, an alkyl group, an alkoxy group, a cycloalkyl group, an alkoxycarbonyl group, an aryl group, an aryloxy group, and the like. Further, R2 may be, for example, a cyclic compound in which two or more alkyl groups and the like form a cycle. More specific examples of R2 may be selected from C1 to C20 alkyl group; C6 to C20 aryl group; C3 to C20 heteroaryl group; C1 to C20 alkyl group in which C3 to C20 heteroaryl is substituted; C6 to C20 aryl group in which C1 to C20 alkyl or C3 to C20 heteroaryl is substituted, and the like.

According to more preferable embodiment of the present invention, a compound represented by the following Chemical Formula 3 may be used as the host.

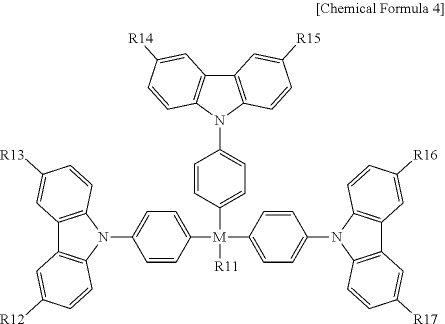

In Chemical Formula 4, the center M is a Group 14 element, preferably, Si or Ge. In addition, in Chemical Formula 4, R11 to R17 may be the same as each other or may be different from each other, and may be selected from an alkyl group.

Specifically, in Chemical Formula 4, R11 to R17 are each alkyl group, the number of carbon atoms of the alkyl group is not limited, but for example, may be selected from C1 to C20 alkyl group. Specific examples of the R11 to R17 may be selected from a methyl group, an ethyl group, a propyl group, a butyl group, and the like, but are not limited thereto. In addition, the propyl group includes n-propyl group and iso-propyl group, and the butyl group includes n-butyl group, iso-butyl group, and tertiary-butyl group. It is more preferred that R11 to R17 are both methyl groups.

The host as described above has high triplet energy (ET) and excellent electrical properties such as charge mobility, and the like, and excellent thermal stability, and the like, to thereby be useful as the emitting layer 30 in the embodiment of the present invention. Specifically, the host as described above has triplet energy (ET≧3.0 eV) of 3.0 eV or more (ET≧3.0 eV). Further, the host material may have excellent charge mobility of 1.0×10⁻³ cm²/v.s or more, preferably 2.0×10⁻³ cm²/v.s or more, and more preferably 3.0×10⁻³ cm²/v.s or more according to the type of the central atom (M) and the carbazole compound (R1). In addition, the host material may have high thermal stability (Tg) of 150° C. or more. Therefore, the host according to the embodiments of the present invention may implement high luminous efficiency together with a deep blue color when the host is applied to the blue PhOLED according to the embodiment of the present invention.

Hereinafter, the embodiments of the present invention will be described in more detail in comparison with Examples and Comparative Examples. The following Examples are set forth to illustrate the present invention, but are not to be construed to limit the technical scope of the present invention.

### Example 1

A thin film containing WO₃ and having work function of 5.9 eV was used as an anode and deposited on a PET substrate, an emitting layer (EML) was formed on the anode (WO₃), and an electron transport layer (ETL) was formed the EML. Then, LiF/Al as a cathode was sequentially formed on the ETL.

Here, the ETL was formed by using the compound represented by Chemical Formula 1 (in Chemical Formula, R′ and R″ are both —CH₃) and having a thickness of 400 nm. In addition, the EML was formed by coating a host on the anode (WO₃) in a thickness of 50 nm and forming a phosphorescent material layer in a thickness of 300 nm, the phosphorescent material layer was obtained by mixing 10 mol % of dopant with the host. As the host, an organic-inorganic composite compound in which M is Ge and R is methyl group (—CH₃) in Chemical Formula 4 was used, and the dopant, FIr6 was used.

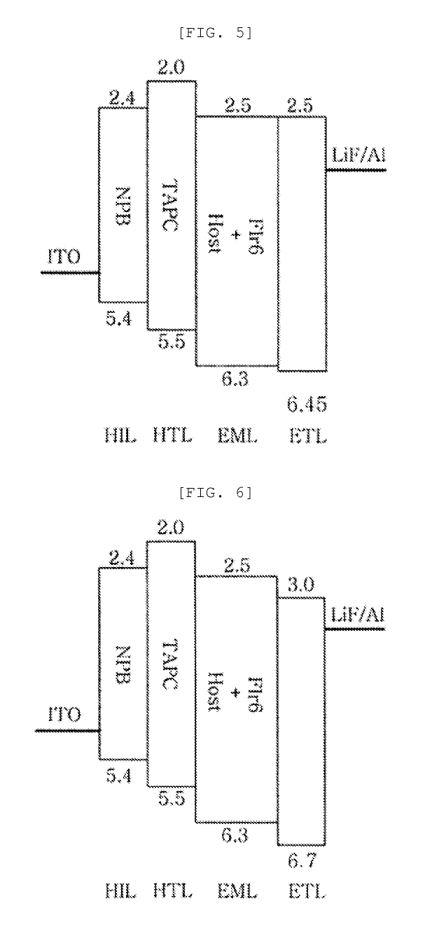

Energy band diagram of the PhOLED manufactured according to Example 1 above was shown in FIG. 3.

### Example 2

Example 2 was performed as the same as Example 1 above except for using compound represented by Chemical Formula 2 (in Chemical Formula 2, R′ and R″ are both —CH₃) as the ETL.

Energy band diagram of the PhOLED manufactured according to Example 2 above was shown in FIG. 4.

### Comparative Example 1

An indium thin oxide (ITO) thin film having work function of 5.2 eV according to the related art was used as an anode and deposited on a PET substrate, NPB (thickness: 300 nm) as a hole injection layer (HIL) and TAPC (thickness: 150 nm) as a hole transport layer (HTL) were formed on the anode (ITO), and then, an emitting layer (EML) was formed on the HTL. The EML was obtained by mixing 10 mol % of dopant with the host, wherein general CBP was used as the host and FIr6 was used as the dopant.

In addition, the ETL was formed on the EML, wherein in order to compare with the ETL of Example 1, the ETL was formed by using the compound which is the same as that of Example 1 (in Chemical Formula, R′ and R″ are both —CH₃) and having a thickness of 400 nm. In addition, LiF/Al as a cathode was formed thereon.

Energy band diagram of the PhOLED manufactured according to Comparative Example 1 above was shown in FIG. 5.

### Comparative Example 2

PhOLED of Comparative Example 2 was prepared by the existing method. Specifically, Comparative Example 2 was performed as the same as Comparative Example 1 above except for using 3TPYMB generally used as ETL.

Energy band diagram of the PhOLED manufactured according to Comparative Example 2 above was shown in FIG. 6.

In the accompanying FIGS. 3 to 6, values of 2.0, 2.4, 2.5 and 3.0 eV shown in upper portions were LUMO energy level, and values of 5.4, 5.5, 6.1, 6.3, 6.45 and 6.7 eV shown in lower portions were HOMO energy level.

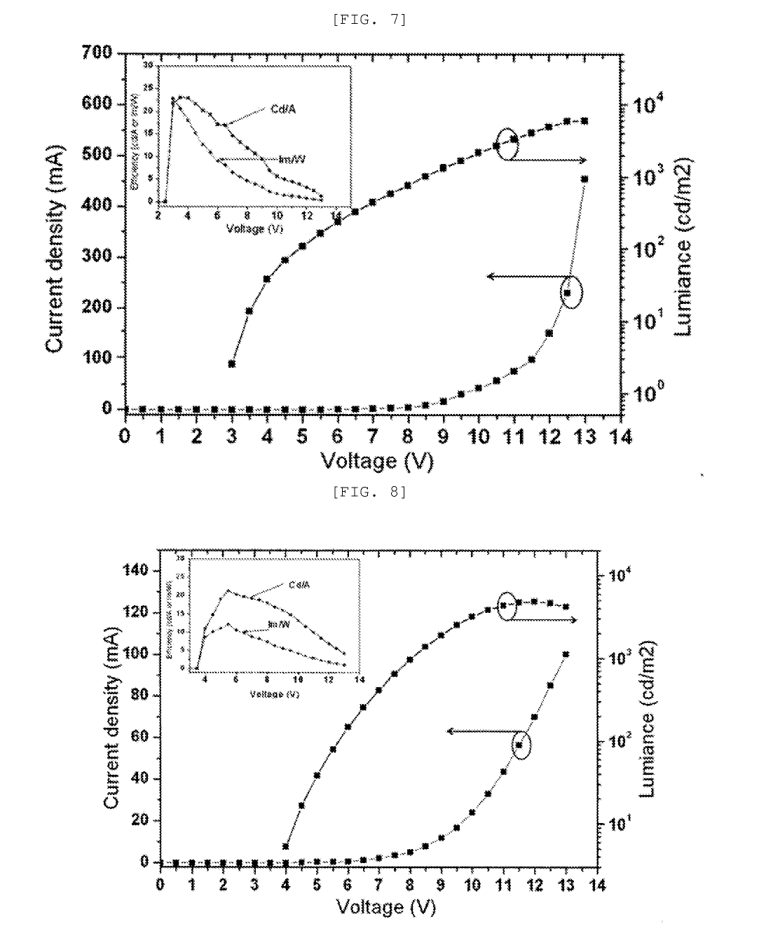

With respect to each PhOLED manufactured according to Examples and Comparative Examples as described above, device properties such as current density depending on voltage, brightness (cd/A), luminous efficiency (lm/W), color coordinate (CIE), and the like, were evaluated, and result thereof was shown in the following Table 1. In addition, Evaluation result of device properties of the PhOLED manufactured according to Example 2 and Comparative Example 2 was shown in FIGS. 7 and 8 as graphs, respectively. FIG. 7 is a graph showing evaluation of device properties of the PhOLED according to Example 2 above and FIG. 8 is a graph showing evaluation of device properties of the PhOLED according to Comparative Example 2 above.

TABLE 1
<Evaluation Result of Device Properties>

| | | Current | | | |
|---|---|---|---|---|---|
| | | Density | | | |
| | Voltage | (@ 12 V) | Max. Eff | | CIE |
| Remarks | [V] | [mA/cm²] | % (Cd/A) | lm/W | (x, y) |
| Example 1 | 4.0 | 120.5 | 15.8(25.0) | 13.7 | (0.15, 0.22) |
| Example 2 | 3.0 | 500.0 | 13.8(23.0) | 13.5 | (0.15, 0.23) |
| Comparative | 4.2 | 73.9 | 15.5(24.9) | 13.6 | (0.15, 0.22) |
| Example 1 | | | | | |
| Comparative | 4.0 | 70.2 | 12.7(21.2) | 11.4 | (0.15, 0.25) |
| Example 2 | | | | | |

It may be appreciated from Table 1 above and the accompanying FIGS. 7 and 8 that even though the PhOLED according to Examples of the present invention does not include the HIL and the HTL, current density at a low voltage of 3V to 5V and excellent device properties such as brightness (Cd/A), luminous efficiency (lm/W), and the like, may be obtained as compared to the existing PhOLED according to Comparative Example 2.

### INDUSTRIAL APPLICABILITY

The present invention provides a blue phosphorescent organic light emitting device having a minimal lamination structure capable of not only showing excellent properties as a blue phosphorescent device, but also being simply manufactured and having a thin thickness due to the minimal lamination structure, to thereby be practically useful in a flexible display, and the like.

1. A blue phosphorescent organic light emitting device comprising:
an anode;
an emitting layer formed on the anode and including a host and a dopant;
an electron transport layer formed on the emitting layer; and
a cathode formed on the electron transport layer,
wherein a difference between a work function of the anode and a high occupied molecular orbital (HOMO) energy level of the emitting layer is less than 1.0 eV, and a difference between a low occupied molecular orbital (LUMO) energy level of the emitting layer and an LUMO energy level of the electron transport layer is less than 1.0 eV.

2. The blue phosphorescent organic light emitting device of claim 1, wherein the difference between the work function of the anode and the high occupied molecular orbital (HOMO) energy level of the emitting layer is 0.1 to 0.9 eV.

3. The blue phosphorescent organic light emitting device of claim 1, wherein the work function of the anode is 5.8 to 6.8 eV.

4. The blue phosphorescent organic light emitting device of claim 1, wherein the anode contains tungsten oxide (WO₃).

5. The blue phosphorescent organic light emitting device of claim 1, wherein the difference between the low occupied molecular orbital (LUMO) energy level of the emitting layer and the LUMO energy level of the electron transport layer is 0.1 to 0.9 eV.

6. The blue phosphorescent organic light emitting device of claim 1, wherein the LUMO energy level of the electron transport layer is 2.9 to 3.1 eV.

7. The blue phosphorescent organic light emitting device of claim 1, wherein the emitting layer includes a host thin film layer formed on the anode; and
a phosphorescent material layer formed on the host thin film layer and containing a host and a dopant.

8. The blue phosphorescent organic light emitting device of claim 1, wherein the electron transport layer includes at least one selected from the following compounds represented by Chemical Formulas 1 and 2: 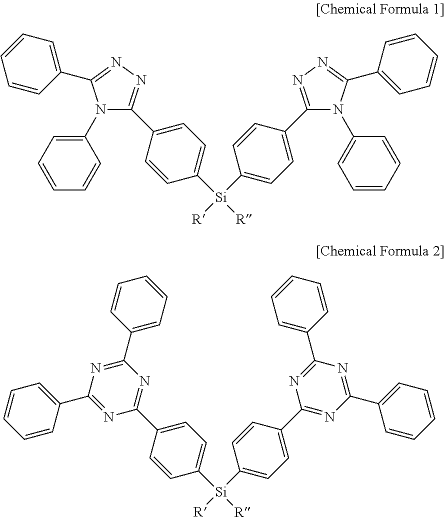
in Chemical Formulas 1 and 2, R′ and R″ are each selected from hydrogen, an aliphatic compound, and an aromatic compound.

9. The blue phosphorescent organic light emitting device of claim 8, wherein R′ and R″ of Chemical Formulas 1 and 2 are each alkyl group or phenyl group.

10. The blue phosphorescent organic light emitting device of claim 1, wherein in the host, a carbazole compound is bonded around a central atom, the central atom is a Group 14 element, the number of carbazole compounds bonded around the central atom is 2 or 3, and the carbazole compound includes carbazole in which an alkyl group is substituted.

11. The blue phosphorescent organic light emitting device of claim 10, wherein the host is a compound represented by the following Chemical Formula 3:
(R1)ₙ-M-(R2)₄₋ₙ [Chemical Formula 3]
in Chemical Formula 3,
M is a Group 14 element,
n is 2 or 3,
R1 is a carbazole compound in which an alkyl group is substituted in carbazole, and
R2 is selected from hydrogen, an aliphatic compound, and an aromatic compound.

12. The blue phosphorescent organic light emitting device of claim 10, wherein the host is a compound represented by the following Chemical Formula 4: 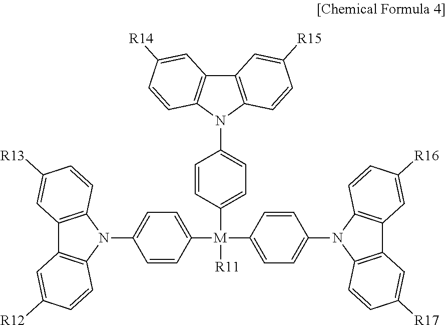
in Chemical Formula 4, M is Si or Ge, and R11 to R17 are each alkyl group.
